(19) United States
(12) Patent Application Publication
(10) Pub. No.: US 2021/0182278 A1
(43) Pub. Date: Jun. 17, 2021

(54) DEVICE MANAGEMENT APPARATUS, DEVICE MANAGEMENT METHOD, AND COMPUTER READABLE MEDIUM

(71) Applicant: Mitsubishi Electric Corporation, Tokyo (JP)

(72) Inventor: Satoshi KAEDE, Tokyo (JP)

(73) Assignee: Mitsubishi Electric Corporation, Tokyo (JP)

(21) Appl. No.: 17/184,136

(22) Filed: Feb. 24, 2021

Related U.S. Application Data
(63) Continuation of application No. PCT/JP2018/042095, filed on Nov. 14, 2018.

(51) Int. Cl. G06F 16/23; G06F 16/901; B61L 25/02; B61L 25/04

(52) U.S. Cl. CPC G06F 16/2379; G06F 16/9024; G06F 30/10; B61L 25/04; B61L 25/028

(57) ABSTRACT

An information integration unit (110) generates integrated data (500) based on individual device data (300) and composite device data (400). The individual device data includes, for each individual device, an individual device identifier (311) and an other-device identifier (314) of each of one or more other devices. The composite device data includes, for each set of a composite device, a composite device identifier (421), time period information (424, 425), and an individual device identifier (423) of each of one or more individual devices. The integrated data includes link information (520) for each set of an individual device and one of one or more other devices, and includes link information (530) for each set of a composite device and an individual device. The link information (530) associating the composite device and the individual device with each other includes time period information (522) indicating a time period in which the individual device has been used for the composite device.

### CROSS REFERENCE TO RELATED APPLICATION

This application is a Continuation of PCT International Application No. PCT/JP2018/042095, filed on Nov. 14, 2018, which is hereby expressly incorporated by reference into the present application.

### TECHNICAL FIELD

The present invention relates to a technique for managing operation data of devices.

### BACKGROUND ART

There is a management apparatus that converts a hierarchical structure of design information of devices and manufacturing information of devices into a graph structure, and utilizes that graph structure.

Patent Literature 1 proposes a method in which link information between related parts is created based on design information including a parts list, and a range of influence of a specific part is searched for.

Patent Literature 2 proposes a method in which a plurality of pieces of parts information are managed in a graph structure, and only information associated with an intended use is selected.

Patent Literature 3 proposes a method in which in order to search for a range of influence of changing a specific part, a graph structure before design is changed and a graph structure after design is changed are compared to detect changed portions.

### CITATION LIST

### Patent Literature

Patent Literature 1: JP 2008-083798 A

Patent Literature 2: JP 2016-139225 A

Patent Literature 3: JP 2014-197279 A

### SUMMARY OF INVENTION

### Technical Problem

With the existing methods, relations between parts can be managed using a parts list of a device, provided that monitoring data is managed on a per device basis.

However, when a composite structure in which devices are combined in a complex manner is operated, it is necessary to accumulate monitoring data of each device on a per composite structure basis. For example, in the composite structure, a plurality of devices operate in cooperation by exchanging signal information. Then, based on time stamps shared in the composite structure, signal information between devices and monitoring data between devices are analyzed. On the other hand, in order to analyze operation of a single device and performance of the single device, only monitoring data of the device is used. Monitoring data is time-series data that is accumulated over a long period of time at intervals of several hundred milliseconds. Therefore, the amount of monitoring data is enormous.

In maintenance or repair after a composite structure is assembled, there may be a case in which only a single device included in the composite structure or only a single subunit included in a device is replaced to be attached to another composite structure. In this case, in order to analyze the function of the single device and the performance of the single device by the existing methods, it is necessary to extract only data of a period in which the device has operated from monitoring data that is managed on a per composite structure basis. If monitoring data of each device included in the composite structure is also to be managed, monitoring data of the composite structure and monitoring data of each device will be managed overlappingly, and the capacity required for accumulating monitoring data will be bloated.

In the method of Patent Literature 1 and the method of Patent Literature 2, arranging hierarchical information of manufacturing and design in a graph structure allows a plurality of parts that are associated with each other to be searched for. However, data of a time period in which each part has been used cannot be identified based on monitoring data that is managed on a per composite structure basis. Even by the method of Patent Literature 3, data of a time period in which each part has been used cannot be identified based on monitoring data that is managed on a per composite structure basis.

It is an object of the present invention to allow operation data concerning an individual device to be acquired from operation data that is managed on a per composite device basis, even when the individual device has been used for different composite devices in different time periods.

### Solution to Problem

A device management apparatus according to the present invention includes an information integration unit.

The information integration unit generates integrated data based on individual device data and composite device data.

The individual device data includes, for each individual device, an individual device identifier and an other-device identifier of each of one or more other devices used for the individual device.

The composite device data includes, for each set of a composite device, a composite device identifier, time period information indicating each time period, and an individual device identifier of each of one or more individual devices used for the composite device in each time period.

The integrated data includes, for each set of an individual device and one of one or more other devices, link information associating the individual device and the one of one or more other devices with each other, and includes, for each set of a composite device and an individual device, link information associating the composite device and the individual device with each other.

The link information associating the composite device and the individual device with each other includes time period information indicating a time period in which the individual device has been used for the composite device.

### Advantageous Effects of Invention

According to the present invention, integrated data is generated. The integrated data that is generated indicates, for each set of a composite device and an individual device, a time period in which the individual device has been used for the composite device. That is, based on the integrated data, a composite device in which an individual device has been used is identified for each time period.

Therefore, even when an individual device has been used for different composite devices in different time periods, operation data concerning the individual device can be acquired from operation data that is managed on a per composite device basis.

### BRIEF DESCRIPTION OF DRAWINGS

FIG. 1 is a configuration diagram of a device management apparatus 100 in a first embodiment;

FIG. 2 is a configuration diagram of a storage unit 130 in the first embodiment;

FIG. 3 is a configuration diagram of design data 200 in the first embodiment;

FIG. 4 is a configuration diagram of manufacturing data 300 in the first embodiment;

FIG. 5 is a configuration diagram of configuration data 400 in the first embodiment;

FIG. 6 is a configuration diagram of integrated data 500 in the first embodiment;

FIG. 7 is a configuration diagram of operation data 600 in the first embodiment;

FIG. 8 is a flowchart of a design-manufacturing integration process (S100) in the first embodiment;

FIG. 9 is a flowchart of an integrated data generation process (S110) in the first embodiment;

FIG. 10 is a flowchart of an integrated data generation process (S120) in the first embodiment;

FIG. 11 is a flowchart of an integrated data generation process (S130) in the first embodiment;

FIG. 12 is a flowchart of a manufacturing-configuration integration process (S200) in the first embodiment;

FIG. 13 is a flowchart of an integrated data generation process (S210) in the first embodiment;

FIG. 14 is a flowchart of an integrated data generation process (S220) in the first embodiment;

FIG. 15 is a flowchart of an integrated data search process (S300) in the first embodiment;

FIG. 16 is an overall view of a graph network 700 in the first embodiment;

FIG. 17 is a partial enlarged view of the graph network 700 in the first embodiment;

FIG. 18 is a flowchart of a related individual search process (S310) in the first embodiment;

FIG. 19 is a flowchart of a related individual search process (S320) in the first embodiment;

FIG. 20 is a flowchart of a related formation search process (S400) in the first embodiment;

FIG. 21 is a flowchart of a related formation search process (S410) in the first embodiment;

FIG. 22 is a flowchart of a related formation search process (S420) in the first embodiment;

FIG. 23 is a flowchart of a search query generation process (S500) in the first embodiment;

FIG. 24 is a flowchart of a search query generation process (S510) in the first embodiment;

FIG. 25 is a flowchart of an operation data search process (S600) in the first embodiment;

FIG. 26 is a schematic diagram of a time-series combining process (S605) in the first embodiment; and

FIG. 27 is a hardware configuration diagram of the device management apparatus 100 in the first embodiment.

### DESCRIPTION OF EMBODIMENTS

In the embodiment and drawings, the same elements or corresponding elements are denoted by the same reference sign. Description of an element denoted by the same reference sign as an element that has been described will be suitably omitted or simplified. Arrows in the drawings mainly indicate flows of data or flows of processing.

### First Embodiment

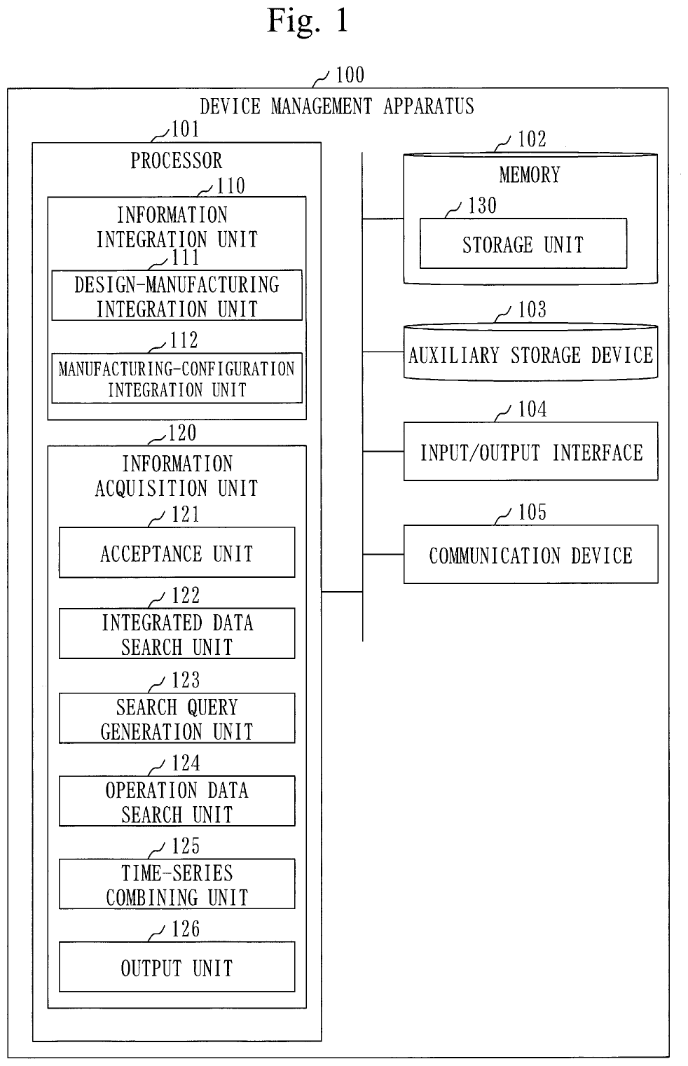

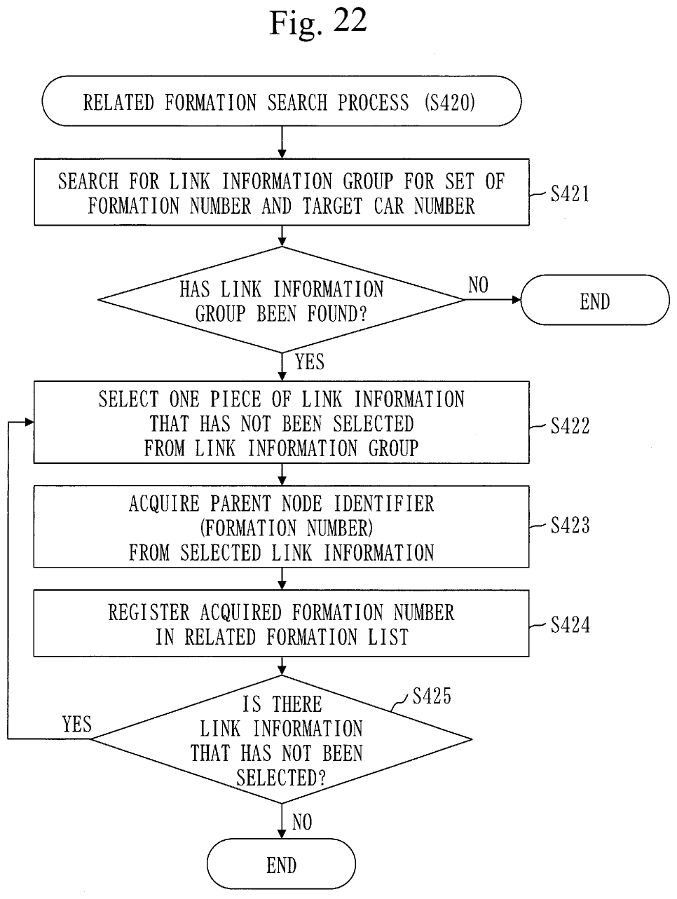

An embodiment in which operation information of each device is managed will be described based on FIGS. 1 to 27.

### Description of Configuration

Based on FIG. 1, a configuration of a device management apparatus 100 will be described.

The device management apparatus 100 is a computer that includes hardware such as a processor 101, a memory 102, an auxiliary storage device 103, an input/output interface 104, and a communication device 105. These hardware components are connected with one another via signal lines.

The processor 101 is an integrated circuit (IC) that performs arithmetic processing, and controls other hardware components. For example, the processor 101 is a central processing unit (CPU), a digital signal processor (DSP), or a graphics processing unit (GPU).

The memory 102 is a volatile storage device. The memory 102 is also called a main storage device or a main memory. For example, the memory 102 is a random access memory (RAM). Data stored in the memory 102 is saved in the auxiliary storage device 103 as necessary.

The auxiliary storage device 103 is a non-volatile storage device. For example, the auxiliary storage device 103 is a read only memory (ROM), a hard disk drive (HDD), or a flash memory. Data stored in the auxiliary storage device 103 is loaded into the memory 102 as necessary.

The input/output interface 104 is a port to which an input device and an output device are connected. For example, the input/output interface 104 is a USB terminal, the input device is a keyboard and a mouse, and the output device is a display. USB is an abbreviation for Universal Serial Bus.

The communication device 105 is a receiver and a transmitter. For example, the communication device 105 is a communication chip or a network interface card (NIC).

The processor 101 includes elements such as an information integration unit 110 and an information acquisition unit 120. These elements are realized by software.

The information integration unit 110 includes a design-manufacturing integration unit 111 and a manufacturing-configuration integration unit 112.

The information acquisition unit 120 includes an acceptance unit 121, an integrated data search unit 122, a search query generation unit 123, an operation data search unit 124, a time-series combining unit 125, and an output unit 126.

The auxiliary storage device 103 stores a device management program for causing a computer to function as the information integration unit 110 and the information acquisition unit 120. The device management program is loaded into the memory 102 and executed by the processor 101.

The auxiliary storage device 103 further stores an operating system (OS). At least part of the OS is loaded into the memory 102 and executed by the processor 101.

That is, the processor 101 executes the device management program while executing the OS.

Data obtained by execution of the device management program is stored in a storage device such as the memory 102, the auxiliary storage device 103, a register in the processor 101, or a cache memory in the processor 101.

The memory 102 functions as a storage unit 130. However, another storage device may function as the storage unit 130 in place of the memory 102 or together with the memory 102.

The device management apparatus 100 may include a plurality of processors as an alternative to the processor 101. The plurality of processors share the role of the processor 101.

The device management program can be recorded (stored) in a computer-readable format in a non-volatile recording medium such as an optical disc or a flash memory.

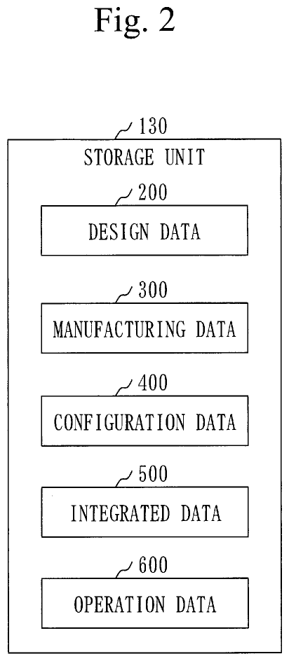

Based on FIG. 2, a configuration of the storage unit 130 will be described.

The storage unit 130 stores design data 200, manufacturing data 300, configuration data 400, integrated data 500, operation data 600, and the like.

These pieces of data are managed using table formats, relational databases, XML databases, or graph databases. In these pieces of data, items can be increased and reduced. XML is an abbreviation for Extensible Markup Language.

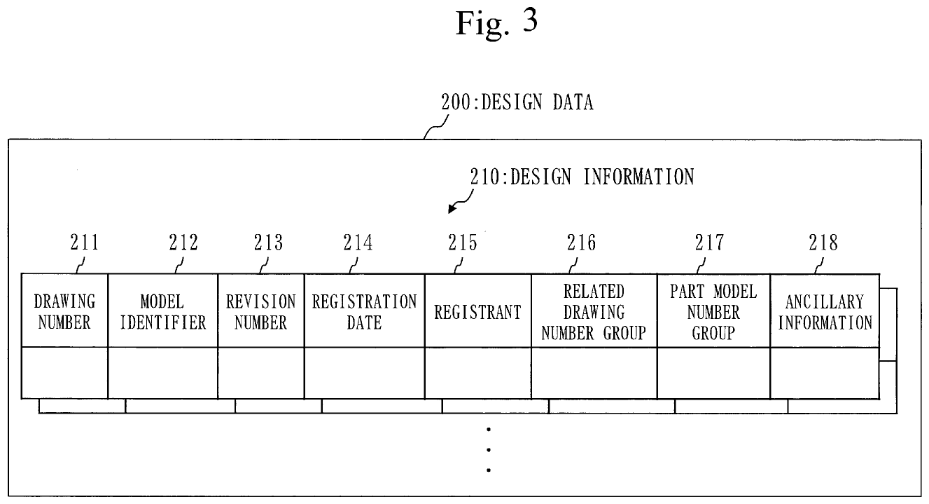

Based on FIG. 3, a configuration of the design data 200 will be described.

The design data 200 is data for managing information generated in a course of designing a device. For example, the design data 200 has a device design model as key information and also has a drawing number, version information, subunit format information, and the like. A subunit is a structure including a plurality of parts.

The design data 200 is equivalent to data called an engineering bill of materials (E-BOM).

The design data 200 includes a plurality of pieces of design information 210.

The design information 210 includes a drawing number 211, a model identifier 212, a revision number 213, a registration date 214, a registrant 215, a related drawing number group 216, a part model number group 217, and ancillary information 218.

The drawing number 211 is an identifier of a document in which design details are written.

The model identifier 212 is an identifier of a designed end product.

The revision number 213 is information for managing revision (for example, a partial change) of the design details.

The registration date 214 is a time stamp at registration of the design information 210.

The registrant 215 is an employee involved in the design information 210.

The related drawing number group 216 is one or more related drawing numbers. A related drawing number is information for managing drawing number of a subunit, related software, and a drawing number of hardware when a designed end product is configured as a composite unit with other designed products.

The part model number group 217 is one or more part model numbers. A part model number is information for identifying a part constituting a designed end product. Depending on the complexity of a device, registered information may reach several hundred items.

The ancillary information 218 is other information related to design.

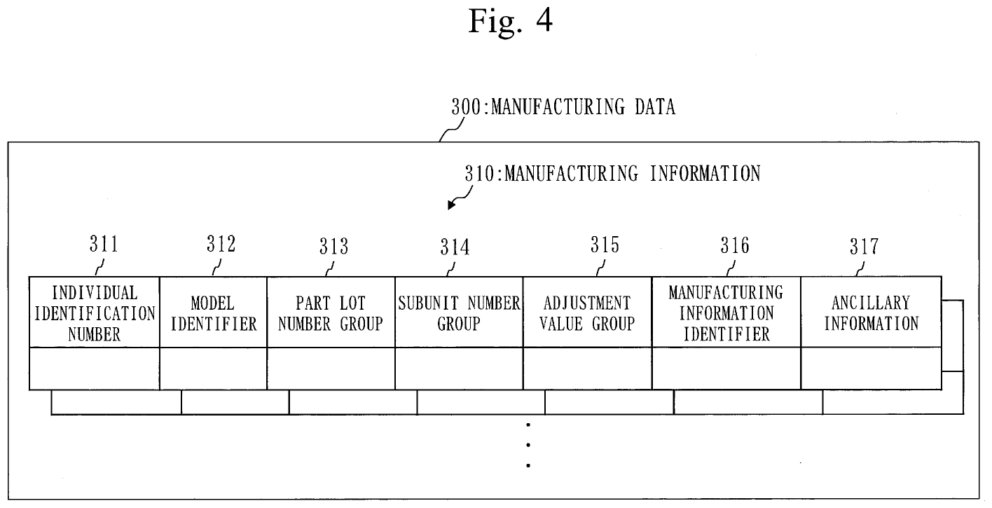

Based on FIG. 4, a configuration of the manufacturing data 300 will be described.

The manufacturing data 300 is data for managing information generated in a course of manufacturing a device. For example, the manufacturing data 300 has model information, which is key information when being associated with design information to be a basis for manufacturing a device. The manufacturing data 300 also has a device individual identification number, lot numbers of parts to be used, an individual identification number of a structure (subunit) including a plurality of parts, and the like.

The manufacturing data 300 is equivalent to data called a manufacturing bill of materials (M-BOM).

The manufacturing data 300 includes a plurality of pieces of manufacturing information 310.

The manufacturing information 310 includes an individual identification number 311, a model identifier 312, a part lot number group 313, a subunit number group 314, an adjustment value group 315, a manufacturing information identifier 316, and ancillary information 317.

The individual identification number 311 is an identifier for individually managing a manufactured device (individual).

The model identifier 312 is information for associating the manufacturing information 310 with the design information 210 that is used in manufacturing. The model identifier 312 corresponds to the model identifier 212 in the design information 210.

The part lot number group 313 is one or more part lot numbers. A part lot number is information for identifying a part used in manufacturing. The part lot number may be a different identifier for identifying a part.

The subunit number group 314 is one or more subunit numbers. A subunit number is an identifier for managing each element (individual) when a device is manufactured by combining a plurality of elements.

The adjustment value group 315 is one or more adjustment values. An adjustment value is information such as an output value or a setting value that is determined depending on a characteristic of a part.

The manufacturing information identifier 316 is an identifier for associating the manufacturing information 310 with information on a device manufacturing step. Information on a device manufacturing step is an identifier of a person in charge of manufacturing, an identifier of a manufacturing machine, or the like.

The ancillary information 317 is other information related to manufacturing.

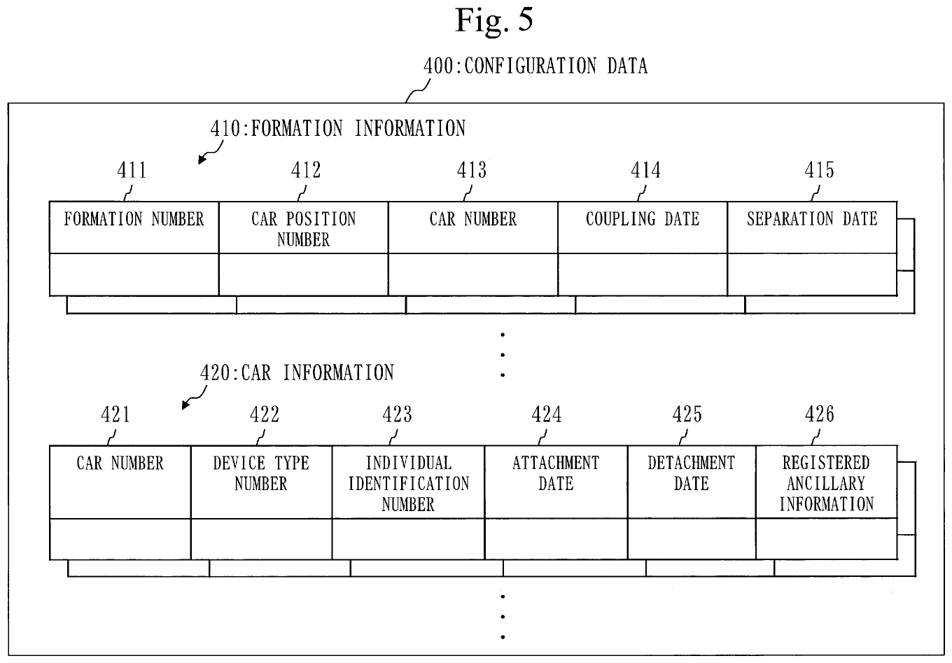

Based on FIG. 5, a configuration of the configuration data 400 will be described.

The configuration data 400 is data for managing information that identifies, in an environment in which a manufactured device (individual) operates, a structure attached to the device. With regard to a railroad car facility, the configuration data 400 has a car position number that identifies a car to which the device is attached, a number that identifies a device installation box to which the device is attached, a number of a train formation that includes a car to which the device is attached, and the like. With regard to a building facility, the configuration data 400 has an address indicating a location of a building in which the device is installed, information that identifies a floor on which the device is installed, information that identifies a facility in which the device is installed, information that identifies an installation location of the device in the facility, and the like.

The configuration data 400 includes a plurality of pieces of formation information 410 and a plurality of pieces of car information 420.

The formation information 410 includes a formation number 411, a car position number 412, a car number 413, a coupling date 414, and a separation date 415.

The formation number 411 is an identifier of a train formation. The train formation is composed of one or more railroad cars.

The car position number 412 identifies a position of a railroad car in the train formation.

The car number 413 is an identifier of the railroad car.

The coupling date 414 is a date on which the railroad car is coupled to the train formation.

The separation date 415 is a date on which the railroad car is separated from the train formation.

There are several types of railroad cars, such as a car body equipped with a motor and a car body not equipped with a motor. A railroad car may be re-coupled in exchange for a railroad car in another train formation.

A set of the formation number 411, the car position number 412, and the car number 413 is managed based on the coupling date 414 and the separation date 415.

The car information 420 includes a car number 421, a device type number 422, an individual identification number 423, an attachment date 424, a detachment date 425, and registered ancillary information 426.

The car number 421 is an identifier of a railroad car.

The device type number 422 identifies a location where a device is attached in the railroad car.

The individual identification number 423 identifies the device.

The attachment date 424 is a date on which the device is attached to the railroad car.

The detachment date 425 is a date on which the device is detached from the railroad car.

The registered ancillary information 426 is information that is cause for attaching the device and information that is cause for detaching the device. For example, it is a reason why the device is detached, a repair type of the device, or the like. Based on the registered ancillary information 426, a history of a relation between the device and a composite device (railroad car) is managed.

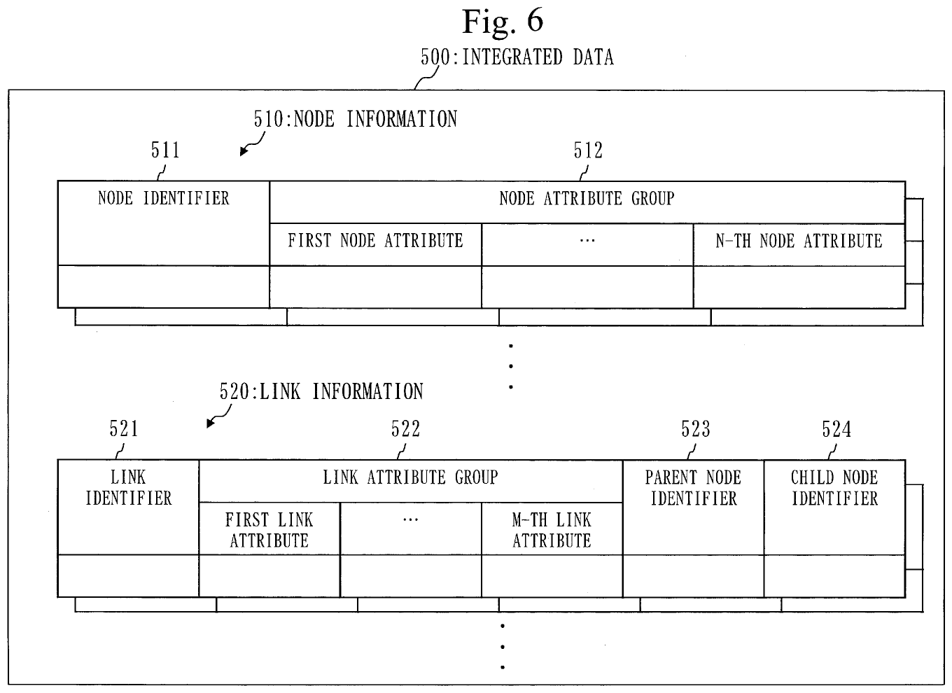

Based on FIG. 6, a configuration of the integrated data 500 will be described.

The integrated data 500 is data for integrating the design data 200, the manufacturing data 300, and the configuration data 400.

The integrated data 500 includes a plurality of pieces of node information 510 and a plurality of pieces of link information 520.

The node information 510 includes a node identifier 511 and a node attribute group 512.

The node identifier 511 identifies a node representing a device.

The node attribute group 512 is one or more node attributes. A node attribute is an attribute of the device.

The link information 520 includes a link identifier 521, a link attribute group 522, a parent node identifier 523, and a child node identifier 524.

The link identifier 521 identifies a link representing a parent-child relation between devices.

The link attribute group 522 is one or more link attributes. A link attribute is an attribute of the parent-child relation.

The parent node identifier 523 identifies a parent node.

The child node identifier 524 identifies a child node.

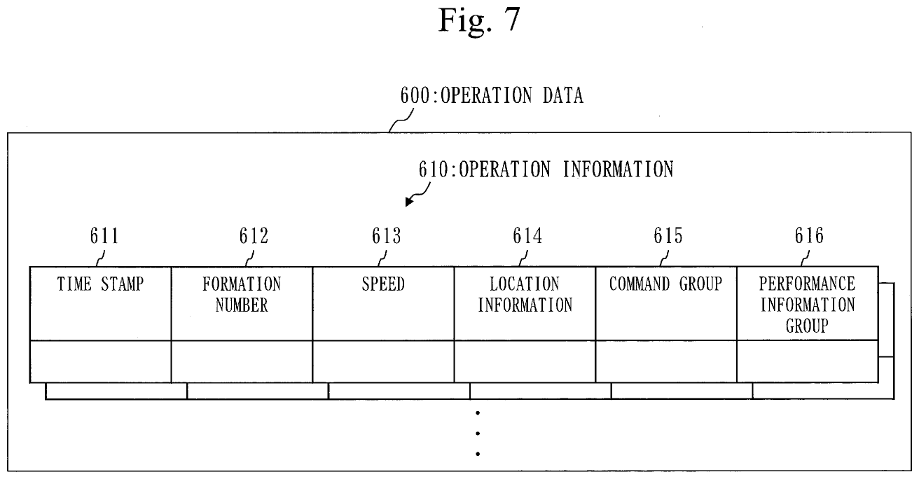

Based on FIG. 7, a configuration of the operation data 600 will be described.

The operation data 600 is data that indicates, in a time series, operating status of a composite device having one or more individual devices as constituent elements.

For example, the operation data 600 indicates operating status of a railroad car in a time series. The railroad car is an example of the composite device. A plurality of railroad cars that are coupled together are called a train formation. A plurality of devices are attached to each car constituting the train formation. For example, devices having functions for causing the railroad car to operate, such an inverter, a motor, an air conditioner, a train information management device, are attached to the railroad car.

The operation data 600 includes a plurality of pieces of operation information 610.

The operation information 610 includes a time stamp 611, a formation number 612, a speed 613, location information 614, a command group 615, and a performance information group 616.

The time stamp 611 indicates the time when the operation information 610 is recorded.

The formation number 612 identifies a train formation.

The speed 613 is a traveling speed of the train formation.

The location information 614 identifies a location of the train formation on a railroad.

The command group 615 is one or more commands in the train formation. For example, a command is information about manipulation of a lever for powering or manipulation of a lever for braking. This information is notified to each device in each railroad car in the train formation. For example, a command is air conditioning temperature information or a door open or close command. These are recognized commonly by each car and each device in the train formation, and cause each car and each device to operate.

The performance information group 616 is one or more pieces of performance information. Performance information is information obtained by monitoring the performance of the device. For example, performance information is information on brake pressure output from a brake control device or information on output from an inverter. For example, performance information is temperature information or humidity information concerning an inlet of an air conditioner. For example, performance information is information on an open/closed state of a door.

### Description of Operation

Operation of the device management apparatus 100 corresponds to a device management method. A procedure of the device management method corresponds to a procedure of a device management program.

The device management method will be described below.

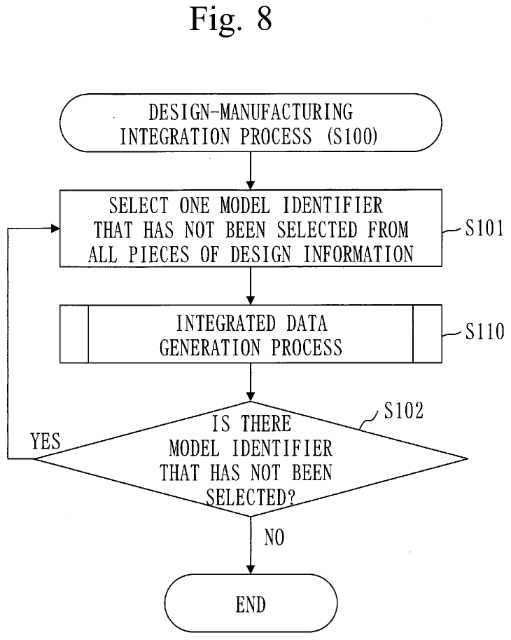

Based on FIG. 8, a design-manufacturing integration process (S100) will be described.

The design-manufacturing integration process (S100) is a process to generate integrated data 500 in order to integrate design data 200 and manufacturing data 300.

In step S101, the design-manufacturing integration unit 111 selects one model identifier 212 that has not been selected from all pieces of design information 210 included in design data 200. Note that those that are the same as any model identifier 212 that has been selected are to be excluded.

In step S110, the design-manufacturing integration unit 111 generates integrated data 500 concerning the selected model identifier 212.

An integrated data generation process (S110) will be described later.

In step S102, the design-manufacturing integration unit 111 determines whether there is a model identifier 212 not selected in step S101 (a model identifier 212 that has not been selected).

If there is a model identifier 212 that has not been selected, the process proceeds to step S101.

If there is no model identifier 212 that has not been selected, the design-manufacturing integration process (S100) ends.

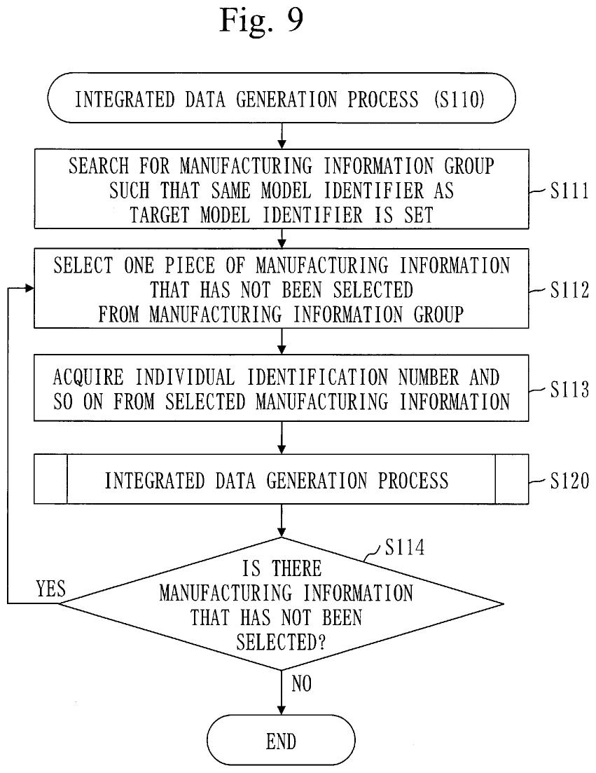

Based on FIG. 9, the integrated data generation process (S110) will be described.

The model identifier 212 selected in step S101 (see FIG. 8) will be referred to as a “target model identifier”.

In step S111, the design-manufacturing integration unit 111 searches for a manufacturing information group such that the same model identifier 212 as the target model identifier is set.

The manufacturing information group is one or more pieces of manufacturing information 310.

In step S112, the design-manufacturing integration unit 111 selects one piece of manufacturing information 310 that has not been selected from the manufacturing information group that has been found.

In step S113, the design-manufacturing integration unit 111 acquires the individual identification number 311, the model identifier 312, and the ancillary information 317 from the selected manufacturing information 310.

In step S120, the design-manufacturing integration unit 111 generates integrated data 500 concerning the acquired individual identification number 311.

An integrated data generation process (S120) will be described later.

In step S114, the design-manufacturing integration unit 111 determines whether there is manufacturing information 310 not selected in step S112 (manufacturing information 310 that has not been selected).

If there is manufacturing information 310 that has not been selected, the process proceeds to step S112.

If there is no manufacturing information 310 that has not been selected, the integrated data generation process (S110) ends.

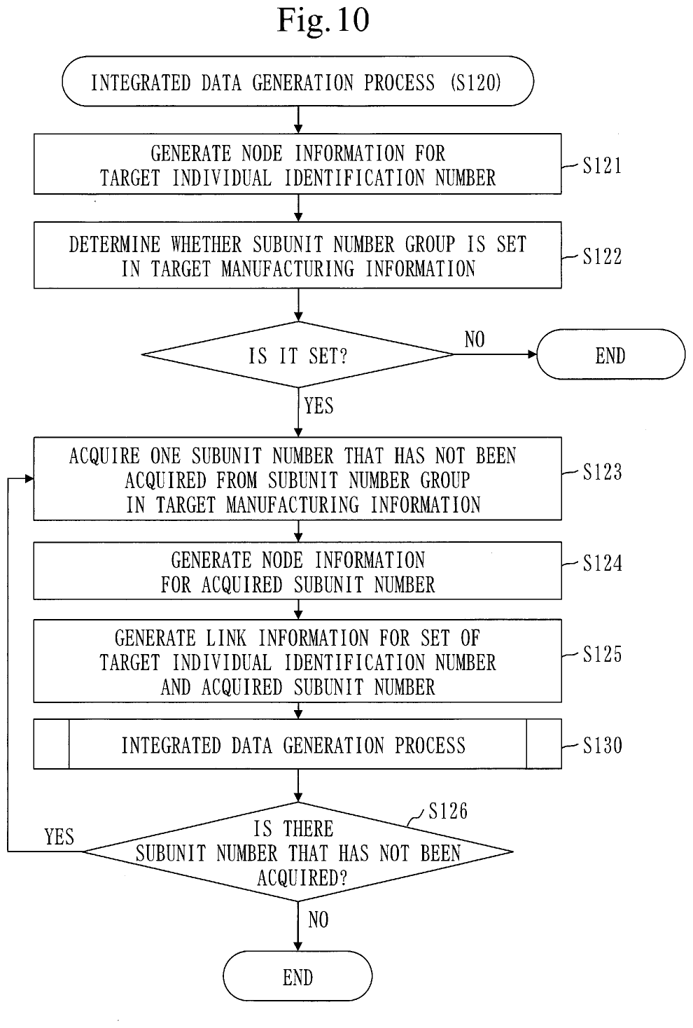

Based on FIG. 10, the integrated data generation process (S120) will be described.

The manufacturing information 310 selected in step S112 (see FIG. 9) will be referred to as “target manufacturing information”.

The individual identification number 311 acquired in step S113 (see FIG. 9) will be referred to as a “target individual identification number”.

In step S121, the design-manufacturing integration unit 111 generates node information 510 for the target individual identification number.

The node information 510 for the target individual identification number is generated as described below.

In the column of the node identifier 511, the target individual identification number is set.

In the column of the node attribute group 512, the model identifier 312 acquired in step S113 (see FIG. 9) is set.

In step S122, the design-manufacturing integration unit 111 determines whether the subunit number group 314 is set in the target manufacturing information.

If the subunit number group 314 is set in the target manufacturing information, the process proceeds to step S123.

If the subunit number group 314 is not set in the target manufacturing information, the integration information generation process (S120) ends.

In step S123, the design-manufacturing integration unit 111 acquires one subunit number that has not been acquired from the subunit number group 314 in the target manufacturing information.

In step S124, the design-manufacturing integration unit 111 generates node information 510 for the acquired subunit number.

The node information 510 for the acquired subunit number is generated as described below.

In the column of the node identifier 511, the acquired subunit number is set.

In the column of the node attribute group 512, the ancillary information 317 acquired in step S113 (see FIG. 9) is set. For example, a manufacturing date or the like is set.

In step S125, the design-manufacturing integration unit 111 generates link information 520 for a set of the target individual identification number and the acquired subunit number.

The link information 520 for the set of the target individual identification number and the acquired subunit number is generated as described below.

In the column of the link identifier 521, a new link identifier is set.

In the column of the parent node identifier 523, the target individual identification number is set.

In the column of the child node identifier 524, the acquired subunit number is set.

In the column of the link attribute group 522, the ancillary information 317 acquired in step S113 (see FIG. 9) is set. For example, an assembly date, a change history version, and the like are set.

In step S130, the design-manufacturing integration unit 111 generates integrated data 500 concerning the acquired subunit number.

An integrated data generation process (S130) will be described later.

In step S126, the design-manufacturing integration unit 111 determines whether there is a subunit number not acquired in step S123 (a subunit number that has not been acquired).

If there is a subunit number that has not been acquired, the process proceeds to step S123.

If there is no subunit number that has not been acquired, the integrated data generation process (S120) ends.

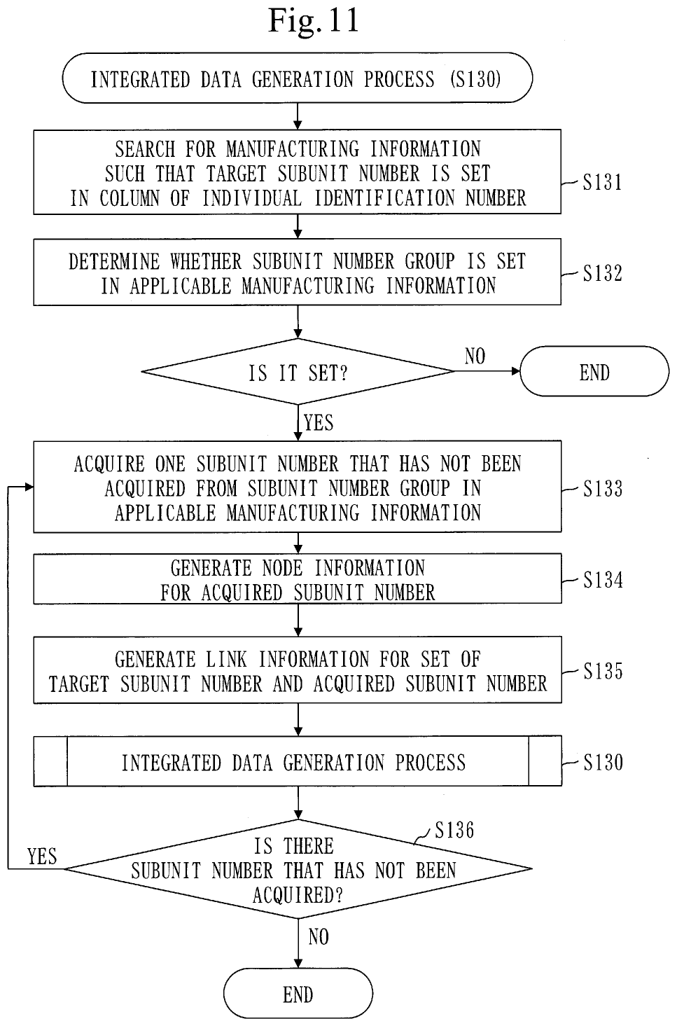

Based on FIG. 11, the integrated data generation process (S130) will be described.

The subunit number acquired in step S123 (see FIG. 10) will be referred to as a “target subunit number”.

In step S131, the design-manufacturing integration unit 111 searches for manufacturing information 310 such that the target subunit number is set in the column of the individual identification number 311.

The manufacturing information 310 that has been found will be referred to as “applicable manufacturing information”.

In step S132, the design-manufacturing integration unit 111 determines whether the subunit number group 314 is set in the applicable manufacturing information.

If the subunit number group 314 is set in the applicable manufacturing information, the process proceeds to step S133.

If the subunit number group 314 is not set in the applicable manufacturing information, the integrated data generation process (S130) ends.

In step S133, the design-manufacturing integration unit 111 acquires one subunit number that has not been acquired from the subunit number group 314 in the applicable manufacturing information.

In step S134, the design-manufacturing integration unit 111 generates node information 510 for the acquired subunit number.

The node information 510 for the acquired subunit number is generated as described below.

In the column of the node identifier 511, the acquired subunit number is set.

In the column of the node attribute group 512, the ancillary information 317 in the applicable manufacturing information is set. For example, a manufacturing date or the like is set.

In step S135, the design-manufacturing integration unit 111 generates link information 520 for a set of the target subunit number and the acquired subunit number.

The link information 520 for the set of the target subunit number and the acquired subunit number is generated as described below.

In the column of the link identifier 521, a new link identifier is set.

In the column of the parent node identifier 523, the target subunit number is set.

In the column of the child node identifier 524, the acquired subunit number is set.

In the column of the link attribute group 522, the ancillary information 317 in the applicable manufacturing information is set. For example, an assembly date, a change history version, and the like are set.

In step S130, the design-manufacturing integration unit 111 generates integrated data 500 concerning the acquired subunit number.

That is, the design-manufacturing integration unit 111 executes the integrated data generation process (S130), using the acquired subunit number as a new target subunit number.

In step S136, the design-manufacturing integration unit 111 determines whether there is a subunit number not acquired in step S133 (a subunit number that has not been acquired).

If there is a subunit number that has not been acquired, the process proceeds to step S133.

If there is no subunit number that has not been acquired, the integrated data generation process (S130) ends.

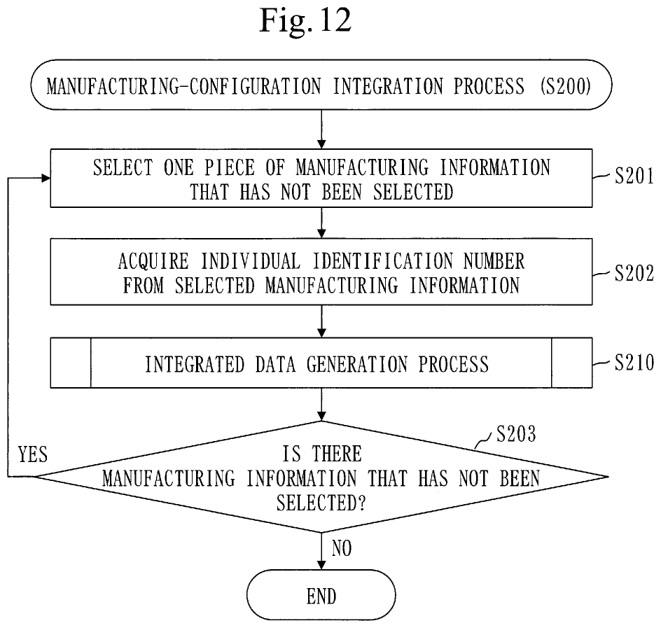

Based on FIG. 12, a manufacturing-configuration integration process (S200) will be described.

The manufacturing-configuration integration process (S200) is a process to generate integrated data 500 in order to integrate manufacturing data 300 and configuration data 400.

In step S201, the manufacturing-configuration integration unit 112 selects one piece of manufacturing information 310 that has not been selected from manufacturing data 300.

In step S202, the manufacturing-configuration integration unit 112 acquires the individual identification number 311 from the selected manufacturing information 310.

In step S210, the manufacturing-configuration integration unit 112 generates integrated data 500 concerning the acquired individual identification number 311.

An integrated data generation process (S210) will be described later.

In step S203, the manufacturing-configuration integration unit 112 determines whether there is manufacturing information 310 not selected in step S201 (manufacturing information 310 that has not been selected).

If there is manufacturing information 310 that has not been selected, the process proceeds to step S201.

If there is no manufacturing information 310 that has not been selected, the manufacturing-configuration integration process (S200) ends.

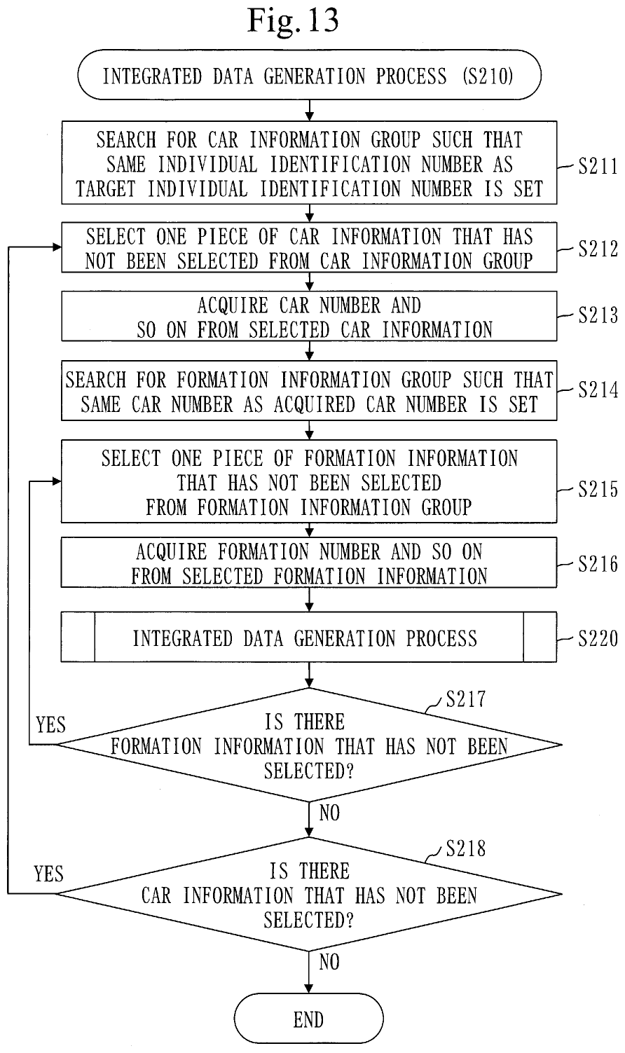

Based on FIG. 13, the integrated data generation process (S210) will be described.

The individual identification number 311 acquired in step S202 (see FIG. 12) will be referred to as a “target individual identification number”.

In step S211, the manufacturing-configuration integration unit 112 searches for a car information group such that the same individual identification number 423 as the target individual identification number is set.

The car information group is one or more pieces of car information 420.

In step S212, the manufacturing-configuration integration unit 112 selects one piece of car information 420 that has not been selected from the car information group that has been found.

In step S213, the manufacturing-configuration integration unit 112 acquires the car number 421, the device type number 422, the individual identification number 423, the attachment date 424, and the detachment date 425 from the selected car information 420.

In step S214, the manufacturing-configuration integration unit 112 searches for a formation information group such that the same car number 413 as the acquired car number 421 is set.

The formation information group is one or more pieces of formation information 410.

In step S215, the manufacturing-configuration integration unit 112 selects one piece of formation information 410 that has not been selected from the formation information group that has been found.

In step S216, the manufacturing-configuration integration unit 112 acquires the formation number 411, the car position number 412, the coupling date 414, and the separation date 415 from the selected formation information 410.

In step S220, the manufacturing-configuration integration unit 112 generates integrated data 500 concerning each of the acquired numbers.

An integrated data generation process (S220) will be described later.

In step S217, the manufacturing-configuration integration unit 112 determines whether there is formation information 410 not selected in step S215 (formation information 410 that has not been selected).

If there is formation information 410 that has not been selected, the process proceeds to step S215.

If there is no formation information 410 that has not been selected, the process proceeds to step S218.

In step S218, the manufacturing-configuration integration unit 112 determines whether there is car information 420 not selected in step S212 (car information 420 that has not been selected).

If there is car information 420 that has not been selected, the process proceeds to step S212.

If there is no car information 420 that has not been selected, the integrated data generation process (S210) ends.

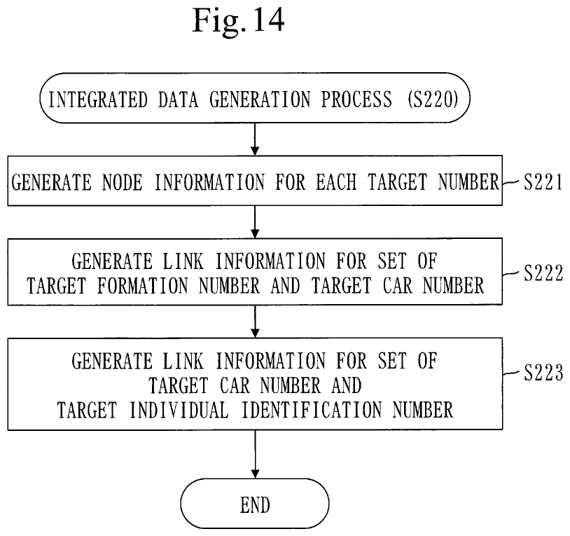

Based on FIG. 14, the integrated data generation process (S220) will be described.

The car number 421 acquired in step S213 (see FIG. 13) will be referred to as a “target car number” or “target number”.

The device type number 422 acquired in step S213 (see FIG. 13) will be referred to as a “target device type number” or “target number”.

The individual identification number 423 acquired in step S213 (see FIG. 13) will be referred to as a “target individual identification number”.

The formation number 411 acquired in step S216 (see FIG. 13) will be referred to as a “target formation number” or “target number.

In step S221, the manufacturing-configuration integration unit 112 generates node information 510 for the target car number.

The node information 510 for the target car number is generated as described below.

In the column of the node identifier 511, the target car number is set.

In the column of the node attribute group 512, the ancillary information 317 in the manufacturing information 310, having set therein the same individual identification number 311 as the target car number, is set. For example, a manufacturing date or the like is set.

Further, the manufacturing-configuration integration unit 112 generates node information 510 for the target formation number.

The node information 510 for the target formation number is generated as described below.

In the column of the node identifier 511, the target formation number is set. In the column of the node attribute group 512, the coupling date 414 acquired in step S216 (see FIG. 13) is set.

In step S222, the manufacturing-configuration integration unit 112 generates link information 520 for a set of the target formation number and the target car number.

The link information 520 for the set of the target formation number and the target car number is generated as described below.

In the column of the link identifier 521, a new link identifier is set.

In the column of the parent node identifier 523, the target formation number is set.

In the column of the child node identifier 524, the target car number is set.

In the column of the link attribute group 522, the car position number 412, the coupling date 414, and the separation date 415 acquired in step S216 (see FIG. 13) are set.

In step S223, the manufacturing-configuration integration unit 112 generates link information 520 for a set of the target car number and the target individual identification number.

The link information 520 for the set of the target car number and the target individual identification number is generated as described below.

In the column of the link identifier 521, a new link identifier is set.

In the column of the parent node identifier 523, the target car number is set.

In the column of the child node identifier 524, the target individual identification number is set.

In the column of the link attribute group 522, the attachment date 424, the detachment date 425, and the device type number 422 acquired in step S213 (see FIG. 13) are set.

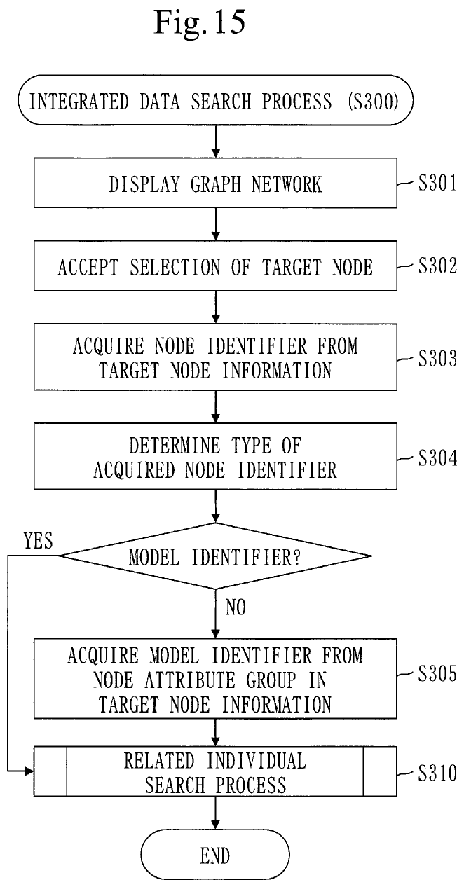

Based on FIG. 15, an integrated data search process (S300) will be described.

The integrated data search process (S300) is a process to identify one or more devices related to a specified device, using integrated data 500.

The specified device is a device that is specified as a search target. Specifically, the device represented by a target node to be described later is the specified device.

In step S301, the acceptance unit 121 generates a graph network using integrated data 500.

Then, the acceptance unit 121 displays the generated graph network on a display.

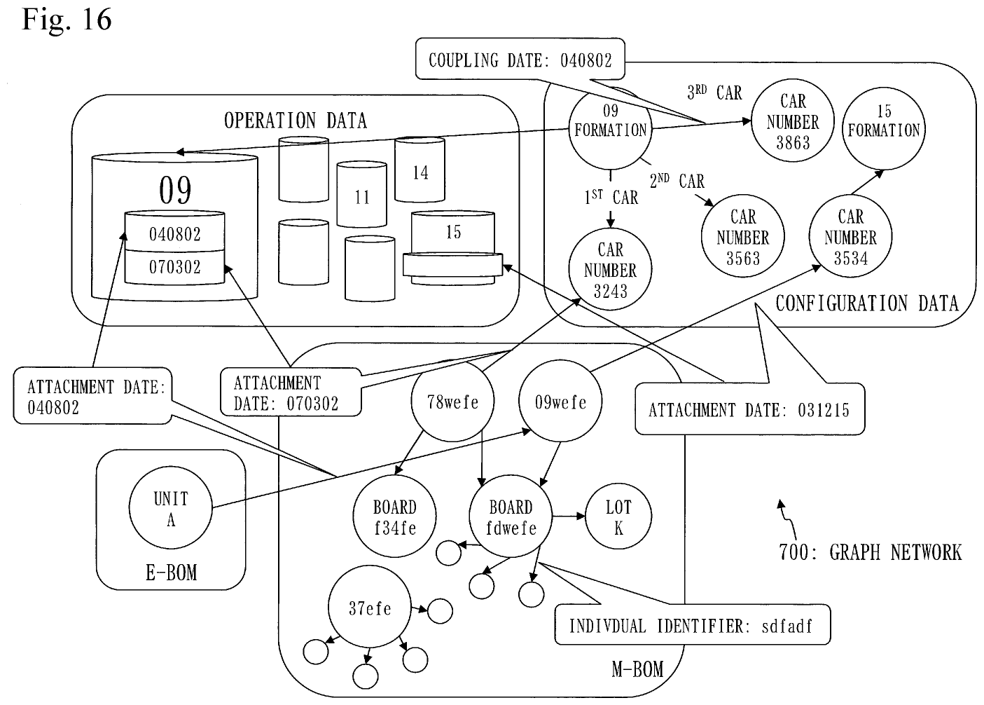

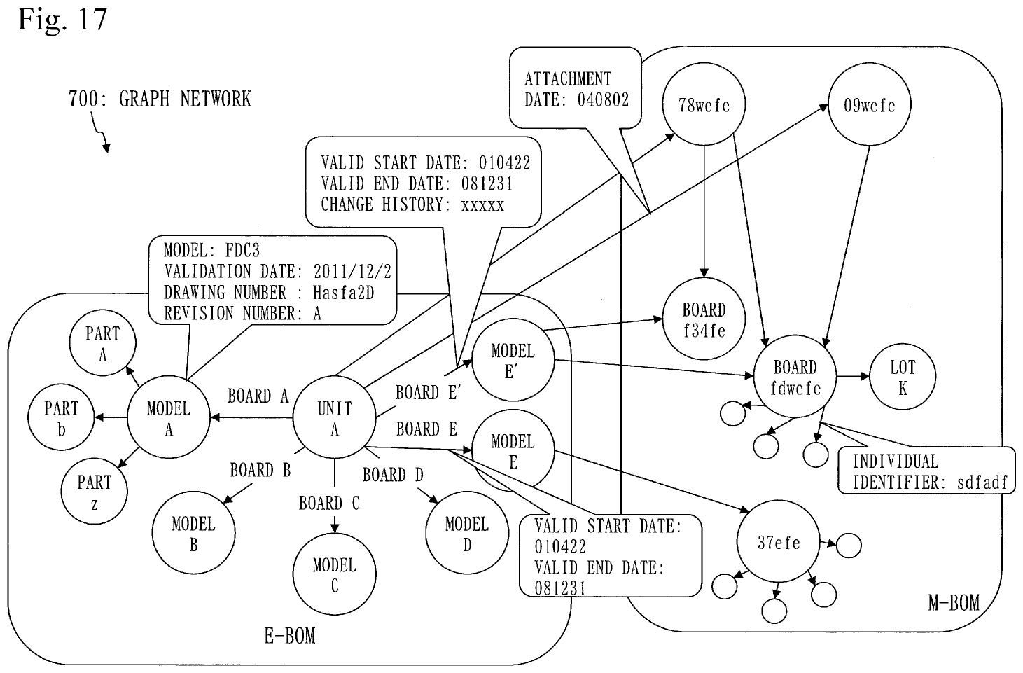

Based on FIGS. 16 and 17, a graph network 700 will be described.

FIG. 16 is an overall view of the graph network 700.

FIG. 17 is a partial enlarged view of the graph network 700.

The graph network 700 has a plurality of nodes and a plurality of links.

A node represents a device. A round figure is a node.

A link connects two nodes that have a parent-child relation. An arrow line is a link. A node connected to the start point of the arrow line is a parent node, and a node connected to the end point (arrow) of the allow line is a child node. A link is also called an edge.

In a balloon attached to a node, a node attribute is written. In a balloon attached to a link, a link attribute is written.

Referring back to FIG. 15, the description continues from step S302.

In step S302, a user selects one node representing an element for which a search is to be performed from the displayed graph network. The selected node will be referred to as a “target node”.

Then, the acceptance unit 121 accepts the selection of the target node. The node information 510 corresponding to the target node will be referred to as “target node information”.

In step S303, the integrated data search unit 122 acquires the node identifier 511 from the target node information.

Specifically, the individual identification number 311 or the model identifier 312 is acquired.

In step S304, the integrated data search unit 122 determines the type of the acquired node identifier 511.

Specifically, the integrated data search unit 122 determines the type of the acquired node identifier 511 based on the format (numbering system or prefix) of information set in the column of the node identifier 511.

If the type of the acquired node identifier 511 is the model identifier 312, the process proceeds to step S310.

If the type of the acquired node identifier 511 is the individual identification number 311, the process proceeds to step S305.

In step S305, the integrated data search unit 122 acquires the model identifier 312 from the node attribute group 512 in the target node information.

Specifically, the integrated data search unit 122 acquires a node attribute that matches the format (numbering system or prefix) for the model identifier 312 from the node attribute group 512.

In step S310, the integrated data search unit 122 searches for the individual identification number 311 concerning the target node, using the integrated data 500.

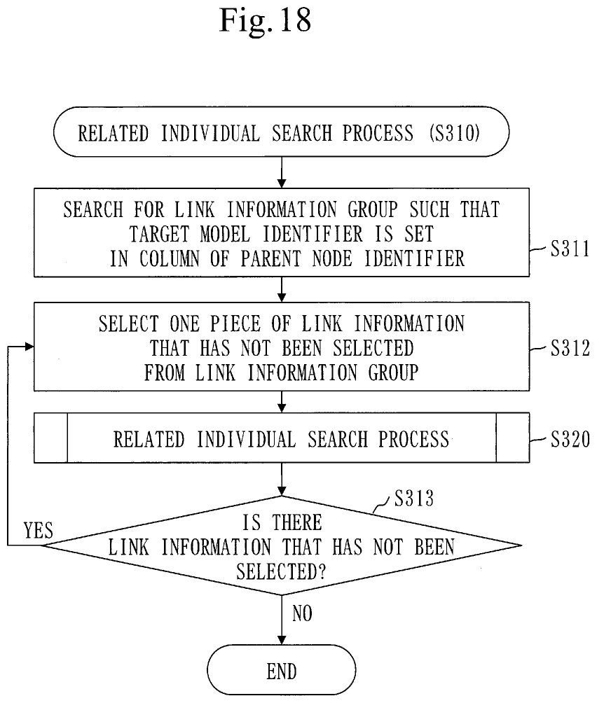

Based on FIG. 18, a related individual search process (S310) will be described.

The model identifier 312 acquired in step S303 or step S305 (see FIG. 15) will be referred to as a “target model identifier”.

In step S311, the integrated data search unit 122 searches for a link information group such that the target model identifier is set in the column of the parent node identifier 523.

The link information group is one or more pieces of link information 520.

In step S312, the integrated data search unit 122 selects one piece of link information 520 that has not been selected from the link information group that has been found.

In step S320, the integrated data search unit 122 searches for the individual identification number 311 concerning the selected link information 520, using the integrated data 500.

A related individual search process (S320) will be described later.

In step S313, the integrated data search unit 122 determines whether there is a link identifier 521 not selected in step S312 (a link identifier 521 that has not been selected).

If there is a link identifier 521 that has not been selected, the process proceeds to step S312.

If there is no link identifier 521 that has not been selected, the related individual search process (S310) ends.

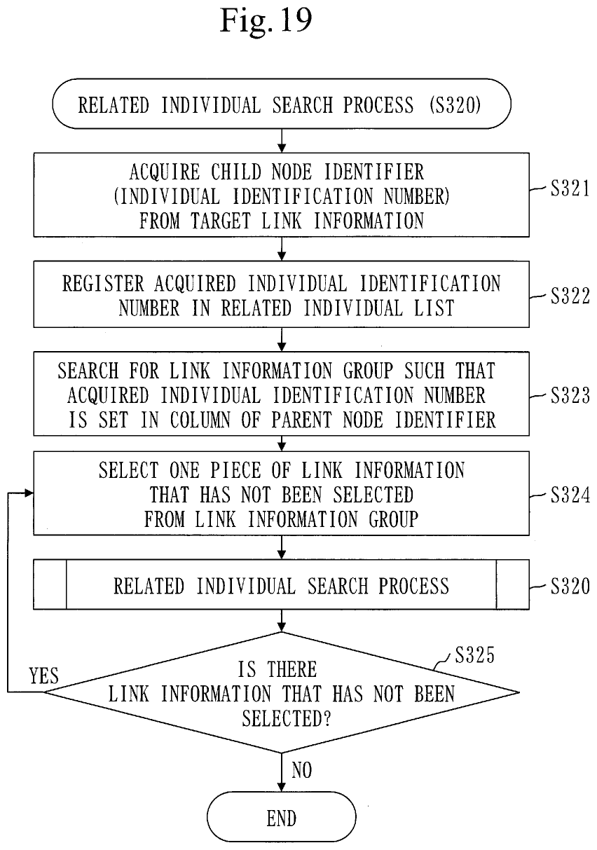

Based on FIG. 19, the related individual search process (S320) will be described.

The link information 520 selected in step S312 (see FIG. 18) will be referred to as a “target link information”.

In step S321, the integrated data search unit 122 acquires the child node identifier 524 from the target link information.

The child node identifier 524 that is acquired is the individual identification number 311.

In step S322, the integrated data search unit 122 registers the acquired individual identification number 311 in a related individual list. The related individual list is stored in the storage unit 130.

In step S323, the integrated data search unit 122 searches for a link information group such that the acquired individual identification number 311 is set in the column of the parent node identifier 523.

The link information group is one or more pieces of link information 520.

In step S324, the integrated data search unit 122 selects one piece of link information 520 that has not been selected from the link information group that has been found.

In step S320, the integrated data search unit 122 searches for the individual identification number 311 concerning the selected link information 520.

That is, the integrated data search unit 122 executes the related individual search process (S320), using the selected link information 520 as new target link information.

In step S325, the integrated data search unit 122 determines whether there is link information 520 not selected in step S324 (link information 520 that has not been selected).

If there is link information 520 that has not been selected, the process proceeds to step S324.

If there is no link information 520 that has not been selected, the related individual search process (S320) ends.

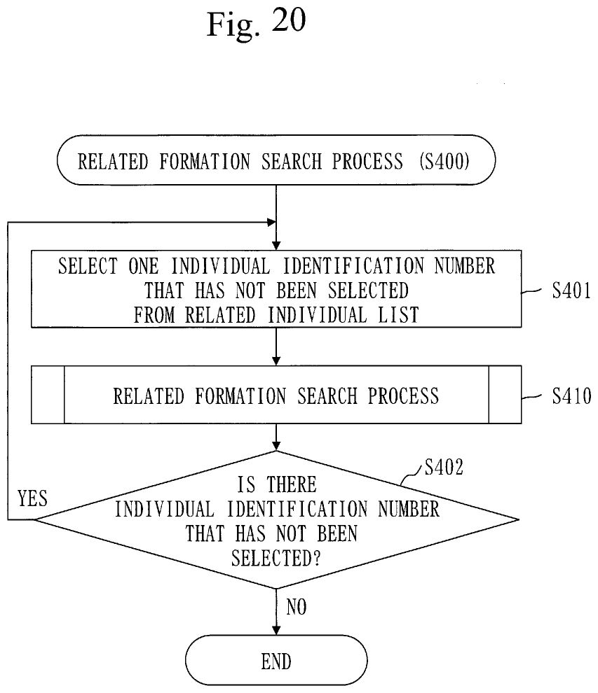

Based on FIG. 20, a related formation search process (S400) will be described.

The related formation search process (S400) is a process to identify one or more composite devices (train formations) related to a specified device, using integrated data 500.

In step S401, the integrated data search unit 122 selects one individual identification number 311 that has not been selected from a related individual list.

In step S410, the integrated data search unit 122 searches for the formation number 411 related to the selected individual identification number 311, using integrated data 500.

A related formation search process (S410) will be described later.

In step S402, the integrated data search unit 122 determines whether there is an individual identification number 311 not selected in step S401 (an individual identification number 311 that has not been selected).

If there is an individual identification number 311 that has not been selected, the process proceeds to step S401.

If there is no individual identification number 311 that has not been selected, the related formation search process (S400) ends.

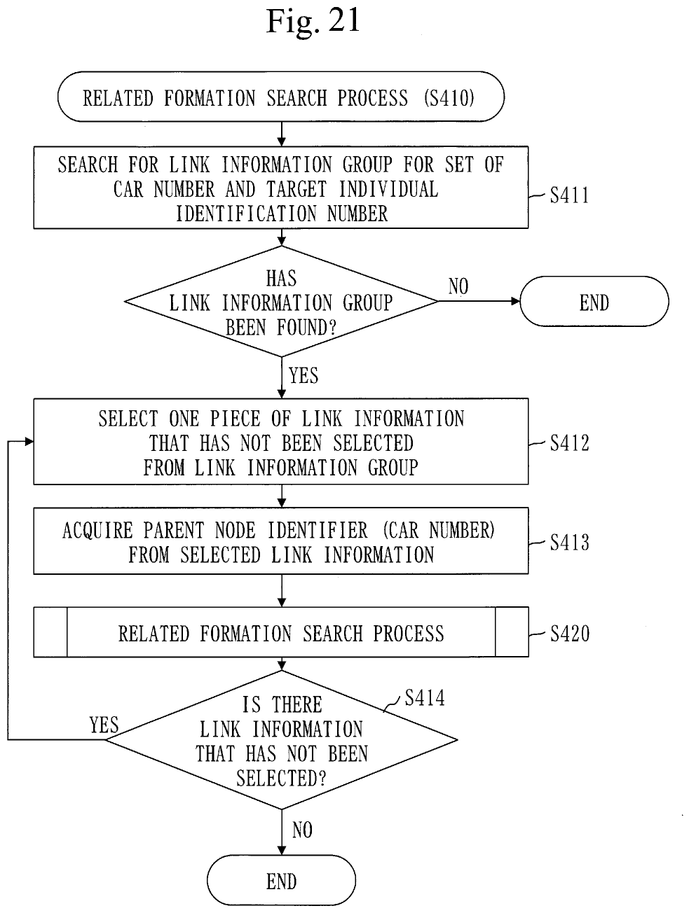

Based on FIG. 21, the related formation search process (S410) will be described.

The individual identification number 311 selected in step S401 (see FIG. 20) will be referred to as a “target individual identification number”.

In step S411, the integrated data search unit 122 searches for a link information group for a set of the car number 421 and the target individual identification number.

The link information group is one or more pieces of link information 520.

Specifically, the integrated data search unit 122 searches for a link information group that satisfies the following two conditions.

A value that matches the format of the car number 421 is set in the column of the parent node identifier 523.

The target individual identification number is set in the column of the child node identifier 524.

If an applicable link information group has been found, the process proceeds to step S412.

If no applicable link information group has been found, the related formation search process (S410) ends.

In step S412, the integrated data search unit 122 selects one piece of link information 520 that has not been selected from the link information group that has been found.

In step S413, the integrated data search unit 122 acquires the parent node identifier 523 from the selected link information 520.

The parent node identifier 523 that is acquired is the car number 421.

In step S420, the integrated data search unit 122 searches for the formation number 411 concerning the acquired car number 421, using the integrated data 500.

A related formation search process (S420) will be described later.

In step S414, the integrated data search unit 122 determines whether there is link information 520 not selected in step S412 (link information 520 that has not been selected).

If there is link information 520 that has not been selected, the process proceeds to step S412.

If there is no link information 520 that has not been selected, the related formation search process (S410) ends.

Based on FIG. 17, the related formation search process (S420) will be described.

The car number 421 acquired in step S413 (see FIG. 21) will be referred to as a “target car number”.

In step S421, the integrated data search unit 122 searches for a link information group for a set of the formation number 411 and the target car number.

The link information group is one or more pieces of link information 520.

Specifically, the integrated data search unit 122 searches for a link information group that satisfies the following two conditions.

A value that matches the format of the formation number 411 is set in the column of the parent node identifier 523.

The target car number is set in the column of the child node identifier 524.

If an applicable link information group has been found, the process proceeds to step S422.

If no applicable link information group has been found, the related formation search process (S420) ends.

In step S422, the integrated data search unit 122 selects one piece of link information 520 that has not been selected from the link information group that has been found.

In step S423, the integrated data search unit 122 acquires the parent node identifier 523 from the selected link information 520.

The parent node identifier 523 that is acquired is the formation number 411.

In step S424, the integrated data search unit 122 registers the acquired formation number 411 in a related formation list associated with the target individual identification number. The related formation list is stored in the storage unit 130.

In step S425, the integrated data search unit 122 determines whether there is link information 520 not selected in step S422 (link information 520 that has not been selected).

If there is link information 520 that has not been selected, the process proceeds to step S422.

If there is no link information 520 that has not been selected, the related formation search process (S420) ends.

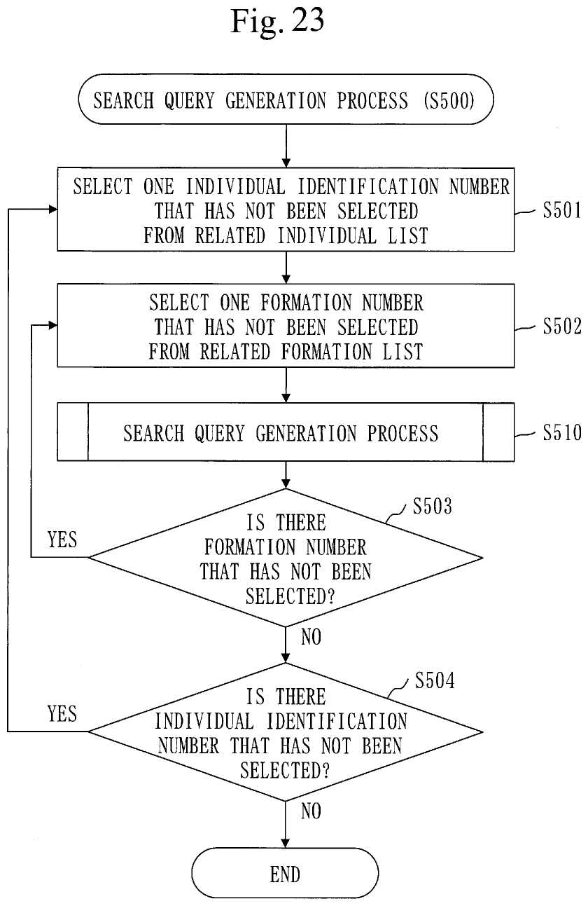

Based on FIG. 23, a search query generation process (S500) will be described.

The search query generation process (S500) is a process to generate a search query for searching for operation information 610 of a specified device at each time point.

In step S501, the search query generation unit 123 selects one individual identification number 311 that has not been selected from a related individual list.

In step S502, the search query generation unit 123 selects one formation number 411 that has not been selected from a related formation list associated with the selected individual identification number 311.

In step S510, the search query generation unit 123 generates a search query concerning a set of the selected individual identification number 311 and the selected formation number 411, using integrated data 500.

A search query generation process (S510) will be described later.

In step S503, the search query generation unit 123 determines whether there is a formation number 411 not selected in step S502 (a formation number 411 that has not been selected).

If there is a formation number 411 that has not been selected, the process proceeds to step S502.

If there is no formation number 411 that has not been selected, the process proceeds to step S504.

In step S504, the search query generation unit 123 determines whether there is an individual identification number 311 not selected in step S501 (an individual identification number 311 that has not been selected).

If there is an individual identification number 311 that has not been selected, the process proceeds to step S501.

If there is no individual identification number 311 that has not been selected, the search query generation process (S500) ends.

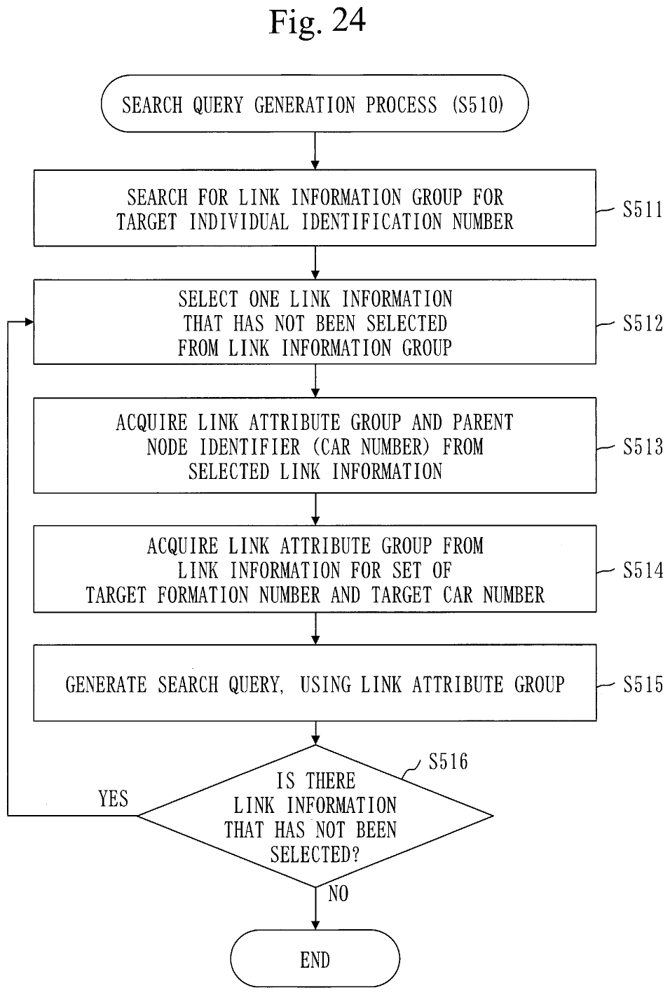

Based on FIG. 24, the search query generation process (S510) will be described.

The individual identification number 311 selected in step S501 (see FIG. 23) will be referred to as a “target individual identification number”.

The formation number 411 selected in step S502 (see FIG. 23) will be referred to as a “target formation number”.

In step S511, the search query generation unit 123 searches for a link information group for the target individual identification number. The link information group is one or more pieces of link information 520.

Specifically, the search query generation unit 123 searches for a link information group such that the target individual identification number is set in the column of the child node identifier 524.

In step S512, the search query generation unit 123 selects a piece of link information 520 that has not been selected from the link information group that has been found.

In step S513, the search query generation unit 123 acquires the link attribute group 522 and the parent node identifier 523 from the selected link information 520.

The link attribute group 522 that is acquired includes the device type number 422, the attachment date 424, and the detachment date 425.

The parent node identifier 523 that is acquired indicates the car number 421. The car number 421 indicated by the acquired parent node identifier 523 will be referred to as a “target car number”.

In step S514, the search query generation unit 123 searches for link information 520 for a set of the target formation number and the target car number.

Specifically, the search query generation unit 123 searches for link information 520 such that the target formation number is set in the column of the parent node identifier 523 and the target car number is set in the column of the child node identifier 524.

Then, the search query generation unit 123 acquires the link attribute group 522 from the link information 520 that has been found.

The link attribute group 522 that is acquired includes the car position number 412.

In step S515, the search query generation unit 123 generates a search query, using the link attribute group 522 acquired in step S513 and the link attribute group 522 acquired in step S514.

Then, the search query generation unit 123 stores the generated search query in the storage unit 130 in association with the target individual identification number.

Specifically, the search query generation unit 123 generates an SQL statement as described below.

In a FROM clause, the formation number 411 is set.

In a SELECT clause, an item of the command group 615 and an item of the performance information group 616 that are stored in operation data 600 and are specified by the car position number 412 and the device type number 422 are set.

In a WHERE clause, the attachment date 424 and the detachment date 425 are set.

In step S516, the search query generation unit 123 determines whether there is link information 520 not selected in step S512 (link information 520 that has not been selected).

If there is link information 520 that has not been selected, the process proceeds to step S512.

If there is no link information 520 that has not been selected, the search query generation process (S510) ends.

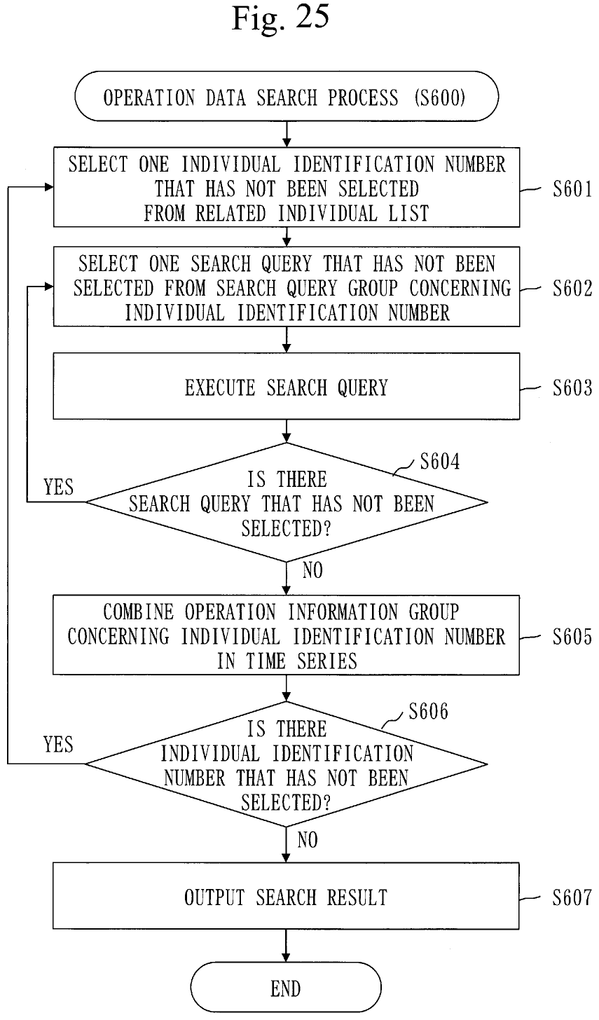

Based on FIG. 25, an operation data search process (S600) will be described.

The operation data search process (S600) is a process to search for operation information 610 of a specified device at each time point.

In step S601, the operation data search unit 124 selects one individual identification number 311 that has not been selected from a related individual list.

In step S602, the operation data search unit 124 selects one search query that has not been selected from a search query group associated with the selected individual identification number 311.

The search query group is one or more search queries.

In step S603, the operation data search unit 124 executes the selected query on the operation data 600.

By this, operation information 610 in each time period concerning the device identified by the individual identification number 311 is obtained.

In step S604, the operation data search unit 124 determines whether there is a search query not selected in step S602 (a search query that has not been selected).

If there is a search query that has not been selected, the process proceeds to step S602.

If there is no search query that has not been selected, the process proceeds to step S605.

By the process from step S602 to step S604, the search query group associated with the selected individual identification number 311 is executed. Then, by the execution of the search query group, an operation information group is obtained. The operation information group is one or more pieces of operation information 610.

In step S605, the time-series combining unit 125 combines one or more pieces of operation information 610 that have been obtained in a time series.

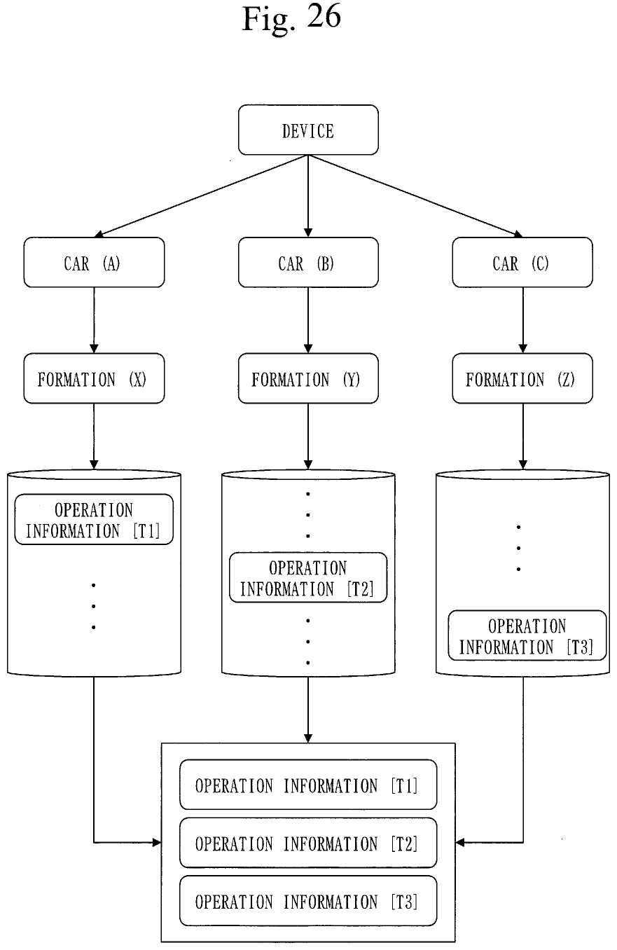

Based on FIG. 26, an overview of searching the integrated data 500, searching the operation data 600 and combining the operation information 610 will be described.

As a result of searching the integrated data 500, the following are found out.

In a time period T1, the device was attached to a car (A) and the car (A) was incorporated in a formation (X).

In a time period T2, the device was attached to a car (B) and the car (B) was incorporated in a formation (Y).

In a time period T3, the device was attached to a car (C) and the car (C) was incorporated in a formation (Z).

By searching the operation data 600, the following pieces of operation information 610 are acquired.

From the operation data 600 of the formation (X), the operation information 610 of the time period T1 is obtained.

From the operation data 600 of the formation (Y), the operation information 610 of the time period T2 is obtained.

From the operation data 600 of the formation (Z), the operation information 610 of the time period T3 is obtained.

Then, the operation information 610 of the time period T1, the operation information 610 of the time period T2, and the operation information 610 of the time period T3 are combined in a time series.

By this, the operation data 600 concerning the specified device is obtained.

Referring back to FIG. 25, the description continues from step S606.

In step S606, the operation data search unit 124 determines whether there is an individual identification number 311 not selected in step S601 (an individual identification number 311 that has not been selected).

If there is an individual identification number 311 that has not been selected, the process proceeds to step S601.

If there is no individual identification number 311 that has not been selected, the process proceeds to step S607.

By the process of step S601 to step S606, one or more pieces of time-series operation information concerning one or more individual identification numbers 311 included in the related individual list are obtained. The time-series operation information is an operation information group combined in a time series.

In step S607, the output unit 126 outputs, as a search result, the one or more pieces of time-series operation information that have been obtained.

For example, the output unit 126 displays the search result on a display.

### Effects of First Embodiment

By the first embodiment, only data of a period in which a specified device has operated can be extracted from monitoring data that is accumulated in a time series on a per composite device basis, without providing a monitoring data accumulation unit for each device. As a result, analyzing deterioration over time or performance on a per device basis is facilitated.

Operation data of a device that is manufactured in association with a specified model identifier (specified device) can be acquired even when the composite device in which the device operates is changed.

Only operation data of a period based on the individual identification number 311 is extracted from time-series data (operation data 600) accumulated on a per composite device basis. Then, extracted data is combined in a time series. This allows operation data of a period after shipment to the present to be acquired on a per device basis. By analyzing the acquired operation data by machine learning or other methods, it is possible to achieve, for example, diagnosis of deterioration of the device or estimation of remaining life of the device.

Information on a change history of an individual device that is managed using configuration data 400 is integrated with design data 200 and manufacturing data 300. This generates integrated data 500. Using the integrated data 500, a graph network configuration is managed. By searching for node information 510 and link information 520, a search query having an operation history of an individual device as a search condition is automatically generated. From operation data 600 that is managed on a per composite device basis, only information of a period in which the individual device has operated is extracted. The extracted information can be combined in a time series. This makes it possible to acquire operation data over time of the individual device and use the acquired operation data over time for analysis of the individual device, without duplicating databases complied on a per individual device basis from the integrated data 500 accumulated on a per composite device basis.

### Other Configurations

Each of the design data 200, the manufacturing data 300, the configuration data 400, the integrated data 500, and the operation data 600 may be stored in an external storage device.

The device management apparatus 100 may include an analysis unit to analyze time-series operation information or a search result. The analysis unit estimates degradation over time of a device or performance of a device by analysis.

### Summary of First Embodiment

In the first embodiment, the device management apparatus as summarized below has been described. The reference signs of the elements in the first embodiment are denoted in parentheses.

A device management apparatus (100) includes an information integration unit (110).

The information integration unit (110) generates integrated data (500) based on individual device data (300) and composite device data (400).

The individual device data includes, for each individual device, an individual device identifier (311) and an other-device identifier (314) of each of one or more other devices used for the individual device.

The composite device data includes, for each set of a composite device, a composite device identifier (421), time period information (424, 425) indicating each time period, and an individual device identifier (423) of each of one or more individual devices used for the composite device in each time period.

The integrated data (500) includes, for each set of an individual device and one of one or more other devices, link information (520) associating the individual device and the one of one or more other devices with each other, and includes, for each set of a composite device and an individual device, link information (530) associating the composite device and the individual device with each other.

The link information (530) associating the composite device and the individual device with each other includes time period information (522) indicating a time period in which the individual device has been used for the composite device.

The device management apparatus (100) includes an information acquisition unit (120).

The information acquisition unit (120) acquires operation information (610) of a specified device at each time point, using operation data (600) and the integrated data (500).

The operation data (600) indicates, for each composite device, operation information (610, 616) at each time point concerning each of one or more individual devices used for the composite device.

The information acquisition unit (120) identifies, for each time period, a composite device for which a specified device has been used, using the integrated data (500). Then, the information acquisition unit (120) acquires, for each identified composite device, operation information (610) of the specified device at each time point from the operation data (600).

The information acquisition unit (120) generates a graph network (700) based on the integrated data (500), and displays the generated graph network (700).

The graph network (700) that is generated represents a relation among one or more individual devices and one or more other devices, and a relation among one or more composite devices and one or more individual devices.

The graph network (700) that is displayed has nodes, each representing a corresponding device of one or more individual devices, one or more other devices, and one or more composite devices.

The specified device is a device corresponding to a node selected from the displayed graph network (700).

A composite device is a train formation or a railroad car.

An individual device is a railroad car to constitute part of the train formation or a unit to be attached to the railroad car.

Each of one or more other devices is a subunit to constitute part of a unit.

### Supplement to First Embodiment

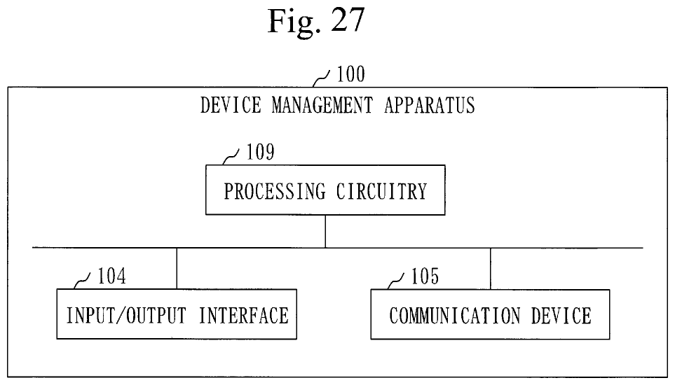

Based on FIG. 27, a hardware configuration of the device management apparatus 100 will be described.

The device management apparatus 100 includes processing circuitry 109.

The processing circuitry 109 is hardware that realizes the information integration unit 110, the information acquisition unit 120, and the storage unit 130.

The processing circuitry 109 may be dedicated hardware, or may be the processor 101 that executes programs stored in the memory 102.

When the processing circuitry 109 is dedicated hardware, the processing circuitry 109 is, for example, a single circuit, a composite circuit, a programmed processor, a parallel-programmed processor, an ASIC, an FPGA, or a combination of these.

ASIC is an abbreviation for Application Specific Integrated Circuit, and FPGA is an abbreviation for Field Programmable Gate Array.

The device management apparatus 100 may include a plurality of processing circuits as an alternative to the processing circuitry 109. The plurality of processing circuits share the role of the processing circuitry 109.

In the processing circuitry 109, some of the functions may be realized by the dedicated hardware, and the rest of the functions may be realized by software or firmware.

As described above, the processing circuitry 109 can be realized by hardware, software, firmware, or a combination of these.

The embodiment is an example of a preferred embodiment, and is not intended to limit the technical scope of the present invention. The embodiment may be implemented partially, or may be implemented in combination with another embodiment. The procedures described using flowcharts or the like may be suitably changed.

The apparatus described in the embodiment may be realized by a plurality of apparatuses. That is, each apparatus described in the embodiment may be realized as a system.

Each element of the apparatus described in the embodiment may be realized by any of software, hardware, firmware, and a combination of these.

Each “unit” may be interpreted as a “process” or “step”.

### REFERENCE SIGNS LIST

100: device management apparatus, 101: processor, 102: memory, 103: auxiliary storage device, 104: input/output interface, 105: communication device, 109: processing circuitry, 110: information integration unit, 111: design-manufacturing integration unit, 112: manufacturing-configuration integration unit, 120: information acquisition unit, 121: acceptance unit, 122: integrated data search unit, 123: search query generation unit, 124: operation data search unit, 125: time-series combining unit, 126: output unit, 130: storage unit, 200: design data, 210: design information, 211: drawing number, 212: model identifier, 213: revision number, 214: registration date, 215: registrant, 216: related drawing number group, 217: part model number group, 218: ancillary information, 300: manufacturing data, 310: manufacturing information, 311: individual identification number, 312: model identifier, 313: part lot number group, 314: subunit number group, 315: adjustment value group, 316: manufacturing information identifier, 317: ancillary information, 400: configuration data, 410: formation information, 411: formation number, 412: car position number, 413: car number, 414: coupling date, 415: separation date, 420: car information, 421: car number, 422: device type number, 423: individual identification number, 424: attachment date, 425: detachment date, 426: registered ancillary information, 500: integrated data, 510: node information, 511: node identifier, 512: node attribute group, 520: link information, 521: link identifier, 522: link attribute group, 523: parent node identifier, 524: child node identifier, 600: operation data, 610: operation information, 611: time stamp, 612: formation number, 613: speed, 614: location information, 615: command group, 616: performance information group, 700: graph network

1. A device management apparatus comprising
processing circuitry to generate integrated data based on individual device data and composite device data, the individual device data including, for each individual device, an individual device identifier and an other-device identifier of each of one or more other devices used for the individual device, the composite device data including, for each set of a composite device, a composite device identifier, time period information indicating each time period, and an individual device identifier of each of one or more individual devices used for the composite device in each time period, the integrated data including, for each set of an individual device and one of one or more other devices, link information associating the individual device and the one of one or more other devices with each other, and including, for each set of a composite device and an individual device, link information associating the composite device and the individual device with each other,
wherein the link information associating the composite device and the individual device with each other includes time period information indicating a time period in which the individual device has been used for the composite device.

2. The device management apparatus according to claim 1,
wherein the processing circuitry acquires operation information of a specified device at each time point, using operation data and the integrated data, the operation data indicating, for each composite device, operation information at each time point concerning each of one or more individual devices used for the composite device.

3. The device management apparatus according to claim 2,
wherein the processing circuitry identifies, for each time period, a composite device for which the specified device has been used, using the integrated data, and acquires, for each identified composite device, operation information of the specified device at each time point from the operation data.

4. The device management apparatus according to claim 2,
wherein the processing circuitry generates a graph network based on the integrated data, and displays the generated graph network, and
the graph network that is generated represents a relation among one or more individual devices and one or more other devices and a relation among one or more composite devices and one or more individual devices.

5. The device management apparatus according to claim 4,
wherein the graph network that is displayed has nodes each representing a corresponding device of one or more individual device, one or more other devices, and one or more composite devices, and
the specified device is a device corresponding to a node selected from the displayed graph network.

6. The device management apparatus according to claim 1,
wherein a composite device is a train formation or a railroad car,
each individual device is a railroad car to constitute part of the train formation or a unit to be attached to the railroad car, and
each of one or more other devices is a subunit to constitute part of a unit.

7. The device management apparatus according to claim 2,
wherein a composite device is a train formation or a railroad car,
each individual device is a railroad car to constitute part of the train formation or a unit to be attached to the railroad car, and
each of one or more other devices is a subunit to constitute part of a unit.

8. The device management apparatus according to claim 3,
wherein a composite device is a train formation or a railroad car,
each individual device is a railroad car to constitute part of the train formation or a unit to be attached to the railroad car, and
each of one or more other devices is a subunit to constitute part of a unit.

9. The device management apparatus according to claim 4,
wherein a composite device is a train formation or a railroad car,
each individual device is a railroad car to constitute part of the train formation or a unit to be attached to the railroad car, and
each of one or more other devices is a subunit to constitute part of a unit.

10. The device management apparatus according to claim 5,
wherein a composite device is a train formation or a railroad car,
each individual device is a railroad car to constitute part of the train formation or a unit to be attached to the railroad car, and
each of one or more other devices is a subunit to constitute part of a unit.

11. The device management apparatus according to claim 3,
wherein the processing circuitry generates a graph network based on the integrated data, and displays the generated graph network, and
the graph network that is generated represents a relation among one or more individual devices and one or more other devices and a relation among one or more composite devices and one or more individual devices.

12. The device management apparatus according to claim 11,
wherein the graph network that is displayed has nodes each representing a corresponding device of one or more individual device, one or more other devices, and one or more composite devices, and
the specified device is a device corresponding to a node selected from the displayed graph network.

13. The device management apparatus according to claim 11,
wherein a composite device is a train formation or a railroad car,
each individual device is a railroad car to constitute part of the train formation or a unit to be attached to the railroad car, and
each of one or more other devices is a subunit to constitute part of a unit.

14. The device management apparatus according to claim 12,
wherein a composite device is a train formation or a railroad car,
each individual device is a railroad car to constitute part of the train formation or a unit to be attached to the railroad car, and
each of one or more other devices is a subunit to constitute part of a unit.

15. A device management method comprising
generating integrated data based on individual device data and composite device data, the individual device data including, for each individual device, an individual device identifier and an other-device identifier of each of one or more other devices used for the individual device, the composite device data including, for each set of a composite device, a composite device identifier, time period information indicating each time period, and an individual device identifier of each of one or more individual devices used for the composite device in each time period, the integrated data including, for each set of an individual device and one of one or more other devices, link information associating the individual device and the one of one or more other devices with each other, and including, for each set of a composite device and an individual device, link information associating the composite device and the individual device with each other,
wherein the link information associating the composite device and the individual device with each other includes time period information indicating a time period in which the individual device has been used for the composite device.

16. A non-transitory computer readable medium storing a device management program for causing a computer to execute
an information integration process of generating integrated data based on individual device data and composite device data, the individual device data including, for each individual device, an individual device identifier and an other-device identifier of each of one or more other devices used for the individual device, the composite device data including, for each set of a composite device, a composite device identifier, time period information indicating each time period, and an individual device identifier of each of one or more individual devices used for the composite device in each time period, the integrated data including, for each set of an individual device and one of one or more other devices, link information associating the individual device and the one of one or more other devices with each other, and including, for each set of a composite device and an individual device, link information associating the composite device and the individual device with each other,
wherein the link information associating the composite device and the individual device with each other includes time period information indicating a time period in which the individual device has been used for the composite device.
